(19) United States
(12) Patent Application Publication
(10) Pub. No.: US 2016/0139195 A1
(43) Pub. Date: May 19, 2016

(54) PROBLEM DETECTION IN CABLE SYSTEM WITH FUSES

(71) Applicant: KONINKLIJKE PHILIPS N.V., Eindhoven (NL)

(72) Inventors: HONG CHEN, Shanghai (CN); LEI FENG, Shanghai (CN)

(21) Appl. No.: 14/900,771

(22) PCT Filed: Jun. 25, 2014
(86) PCT No.: PCT/EP2014/063351

§ 371 Date: Dec. 22, 2015

(30) Foreign Application Priority Data
Jul. 2, 2013 (CN) PCT/CN2013/078674
Oct. 4, 2013 (EP) 13187326.7

(51) Int. Cl. G01R 31/11

(52) U.S. Cl. CPC G01R 31/11

(57) ABSTRACT

Apparatuses (10) report problems in cable systems comprising cables (101) and loads (111) connected to the cables (101) via fuses (121) and comprise first circuits (1) for detecting the fuses (121) going from conducting modes to non-conducting modes or having reached non-conducting modes, second circuits (2) for receiving first pulse signal from devices (20) connected to the cables (101) and in response to receptions of the first pulse signals transmitting second pulse signals to the devices (20) and third circuits (3) for activating the second circuits (2) in response to detection results from the first circuits (1). The devices (20) search for the problems and comprise transmitters (21) for transmitting the first pulse signals to the apparatuses (10) and receivers (22) for receiving the second pulse signals from the apparatuses (10). The second pulse signals are indicative for the problems, and time-intervals between transmissions of the first pulse signals and receptions of the second pulse signals are indicative for locations of the problems.

### FIELD OF THE INVENTION

The invention relates to an apparatus for reporting a problem in a cable system, the cable system comprising a cable and a load connected to the cable via a fuse.

The invention further relates to an arrangement comprising the apparatus, to a device for searching for the problem in the cable system, to the cable system, to a package system, and to a method.

Examples of such a problem are broken fuses. Examples of such a load are lamps and other units that need to be supplied/powered/fed electrically.

### BACKGROUND OF THE INVENTION

CN 101635077 A discloses an anti-theft detection method for a road lamp cable wherein a variable frequency input current signal is injected into the road lamp cable and wherein output current signals and output voltage signals are to be measured for different frequencies of the input current signal and wherein resonance frequencies of road lamps are to be taken into account and wherein a number of actual road lamps needs to be known. This way, in a relatively complex manner, the road lamp cable can be monitored.

CN 201690648 U discloses an intelligent street lamp system based on a wireless sensing network such as GPRS or 3G. This way, in a relatively complex manner, the street lamp system can be monitored.

### SUMMARY OF THE INVENTION

It is an object of the invention to provide an improved apparatus. Further objects of the invention are to provide an arrangement, an improved device, a cable system, a package system and an improved method.

According to a first aspect, an apparatus is provided for reporting a problem in a cable system, the cable system comprising a cable and a load connected to the cable via a fuse, the apparatus comprising:

a first circuit for detecting the fuse going from a conducting mode to a non-conducting mode or having reached a non-conducting mode,

a second circuit for, when activated, receiving a first pulse signal from a device connected to the cable and in response to a reception of the first pulse signal transmitting a second pulse signal to the device, and

a third circuit for activating the second circuit in response to a detection result from the first circuit.

The apparatus reports a problem, such as a broken fuse, in a cable system that comprises a cable and a load connected to the cable via a fuse by receiving a first pulse signal from a device and in response transmitting a second pulse signal back to the device, but only in case it has been detected that the fuse is broken. Thereto, via a first circuit, it is detected that the fuse is going from a conducting mode to a non-conducting mode or has reached a non-conducting mode. The conducting mode is a mode wherein the fuse is conducting and/or is connecting the cable and the load via a relatively small resistance value, such as for example <100 Ohm, preferably <10 Ohm, more preferably <1 Ohm. The non-conducting mode is a mode wherein the fuse is not conducting and/or is not connecting the cable and the load via a relatively small resistance value but is showing at least a relatively large resistance value, such as for example >1 k Ohm, preferably >10 k Ohm, more preferably >100 k Ohm. Via a second circuit, the first pulse signal is received from the device connected to the cable and in response to a reception of the first pulse signal the second pulse signal is transmitted back to the device, but only after the second circuit has been activated. Via a third circuit, the second circuit is activated in response to a detection result from the first circuit. As a result, the apparatus located close to the fuse and/or the load can report the problem to the device located at a central location, which is a great advantage. The second pulse signal is indicative for the problem, and a time-interval between a transmission of the first pulse signal and a reception of the second pulse signal at the device is indicative for a location of the problem.

Other kinds of problems may be reported as well, such as a broken connection between the fuse and the load and/or a missing load and/or a malfunction of the load etc. At a start of the apparatus, such as for example shortly after installation or shortly after a reset, the second circuit will be de-activated and waiting to be activated. In a de-activated mode, the second circuit may be invisible to the cable system and may not have any influence on the cable system.

An embodiment of the apparatus is defined by the second pulse signal being a reflection of the first pulse signal. When being a reflection of the first pulse signal, the second pulse signal may have a smaller amplitude and another polarity than the first pulse signal. An embodiment of the apparatus is defined by a duration of the first pulse signal being smaller than 2 msec. The first pulse signal may be a relatively high-frequency signal, where a feeding signal at 50 Hz or 60 Hz for feeding the loads via the cable is considered to be a relatively low-frequency signal. The frequency of the first pulse could be several times of main power frequency, or more higher, in order to distinguish the reflected signal. Other feeding signals such as direct current feeding signals are not to be excluded.

Preferably, the first pulse is a voltage signal.

An embodiment of the apparatus is defined by the first circuit comprising a detector for detecting a current signal flowing through the load or through the fuse or detecting a voltage signal present across the load or across the fuse or detecting another signal representative for the fuse going from the conducting mode to the non-conducting mode or having reached the non-conducting mode. Many different ways will be possible to detect a mode of the fuse. The detector may comprise a current transformer, a relay coil, a transistor, a thyristor, a triac etc. possibly with further circuitry.

An embodiment of the apparatus is defined by the second circuit comprising a signaling capacitor, and the third circuit comprising a switch. The signaling capacitor is suited for reflecting the first pulse signal into the second pulse signal, and the switch is suited for activating and de-activating the signaling capacitor. Other components are not to be excluded and will be possible too. The switch may comprise a relay contact, a transistor, a thyristor, a triac etc. possibly with further circuitry.

An embodiment of the apparatus is defined by the signaling capacitor and the switch forming part of a first serial connection, the fuse and the load forming part of a second serial connection, the first and second serial connections being coupled in parallel to each other. Other constructions are not to be excluded and will be possible too.

An embodiment of the apparatus is defined by the switch going from a non-conducting mode into a conducting mode in response to the detection result from the first circuit and staying in this conducting mode until a reset of the switch. Preferably, the switch will stay into the conducting mode until the reset of the switch, to allow the first and second pulse signals to be exchanged when the loads are switched off, such as for example, in case the loads comprise lamps, during the day. The conducting mode is a mode wherein the switch is conducting and/or is connecting the signaling capacitor to (both conductors of) the cable via a relatively small resistance value, such as for example <100 Ohm, preferably <10 Ohm, more preferably <1 Ohm. The non-conducting mode is a mode wherein the switch is not conducting and/or is not connecting the signaling capacitor to (both conductors of) the cable via a relatively small resistance value but is showing at least a relatively large resistance value, such as for example >1 k Ohm, preferably >10 k Ohm, more preferably >100 k Ohm. A reset may comprise a local reset, a remote reset and a replacement.

According to a second aspect, an arrangement is provided comprising the apparatus as defined above and further comprising the load and/or the fuse.

According to a third aspect, a device is provided for searching for a problem in a cable system, the cable system comprising a cable and a load connected to the cable via a fuse, the device comprising:

a transmitter for transmitting a first pulse signal to an apparatus as defined above, and

a receiver for receiving a second pulse signal from the apparatus, the second pulse signal being indicative for the problem, and a time-interval between a transmission of the first pulse signal and a reception of the second pulse signal being indicative for a location of the problem.

An embodiment of the device is defined by the second pulse signal being a reflection of and having a smaller amplitude than the first pulse signal.

An embodiment of the device is defined by a duration of the first pulse signal being smaller than 2 msec.

An embodiment of the device is defined by the apparatus comprising a signaling capacitor, and a load coupled to another apparatus comprising a storing capacitor, the device further comprising:

a charger for producing a charging signal for charging the signaling capacitor and the storing capacitor, and

a discharger for discharging the signaling capacitor without discharging the storing capacitor, an amplitude of the first pulse signal being smaller than an amplitude of a voltage signal present across the charged storing capacitor.

A signaling capacitor may for example have a value <1 micro Farad, and a storing capacitor may for example have a value >10 micro Farad. In case the load comprises such a storing capacitor having a capacitance value larger than a capacitance value of the signaling capacitor, two problems may occur. Firstly, the signaling capacitor may no longer reflect the first pulse signal owing to the fact that the storing capacitor of a load connected to another apparatus (which is located closer to the device) may block this first pulse signal and convert it into the reflected second pulse signal that goes back to the device. Secondly, this storing capacitor may reflect the first pulse signal even in case the corresponding fuse is in a conducting mode. To solve these problems, the charger will produce a charging signal for charging the signaling capacitor and the storing capacitor, and the discharger will discharge only the signaling capacitor without discharging the storing capacitor, whereby an amplitude of the first pulse signal should be smaller than an amplitude of a voltage signal present across the charged storing capacitor. This way, the storing capacitor is made invisible to the first pulse signal.

In one embodiment, the load is a LED lamp and the storing capacitor is a bulk capacitor behind the bridge rectifier in the LED driver.

According to a fourth aspect, a cable system is provided comprising a cable and a load connected to the cable via a fuse and further comprising the apparatus as defined above and/or the device as defined above.

According to a fifth aspect, a package system is provided comprising the apparatus as defined above and the device as defined above.

According to a sixth aspect, a method is provided for searching for a problem in a cable system, the cable system comprising a cable and a load connected to the cable via a fuse, the method comprising a first step of transmitting a first pulse signal from a device to an apparatus for reporting the problem in the cable system, the apparatus being arranged to detect the fuse going from a conducting mode to a non-conducting mode or having reached a non-conducting mode, to receive the first pulse signal, and to, in response to a reception of the first pulse signal and in response to a detection result, transmit a second pulse signal to the device, and the method comprising a second step of receiving the second pulse signal, the second pulse signal being indicative for the problem, and a time-interval between a transmission of the first pulse signal and a reception of the second pulse signal being indicative for a location of the problem.

A basic idea is that that a mode of a fuse is to be detected and that in response to a detection result a first pulse signal is to be received and in response to a reception a second pulse signal is to be transmitted.

A problem to provide an improved apparatus and an improved device and an improved method has been solved. A further advantage is that the improved apparatus and the improved device are simple, low cost and robust.

These and other aspects of the invention will be apparent from and elucidated with reference to the embodiments described hereinafter.

### BRIEF DESCRIPTION OF THE DRAWINGS

In the drawings:

FIG. 1 shows a prior art cable system,

FIG. 2 shows an apparatus, a fuse and a load,

FIG. 3 shows a first embodiment of the apparatus,

FIG. 4 shows a second embodiment of the apparatus,

FIG. 5 shows a device,

FIG. 6 shows a problem occurrence,

FIG. 7 shows a problem report, and

FIG. 8 shows a prior art load.

### DETAILED DESCRIPTION OF EMBODIMENTS

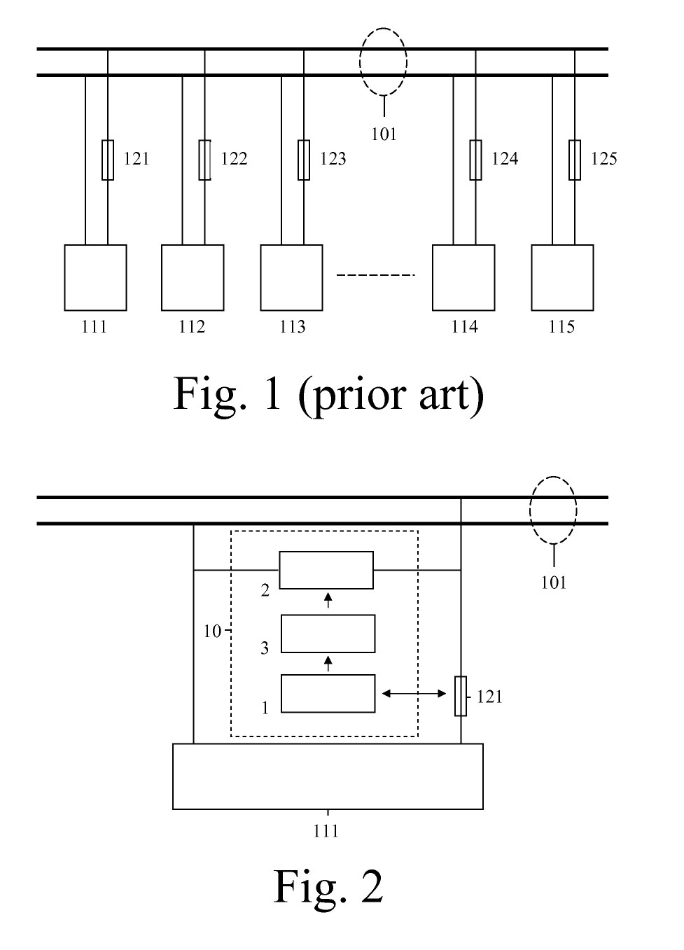

In the FIG. 1, a prior art cable system is shown, comprising a cable 101, loads 111-115 and fuses 121-125. Each load 111-115 is coupled to a first conductor of the cable 101 indirectly via a fuse 121-125 and to a second conductor of the cable directly. The load 111-115 may be any kind of load, such as a lamp, for example comprising one or more light emitting diodes. In one embodiment, the load is a non linear load, like a rectifier load. The impedance of the rectifier load is capacitive. The fuse 121-125 may be any kind of fuse. Alternatively, the second conductor of the cable 101 may be arranged otherwise, for example via the ground.

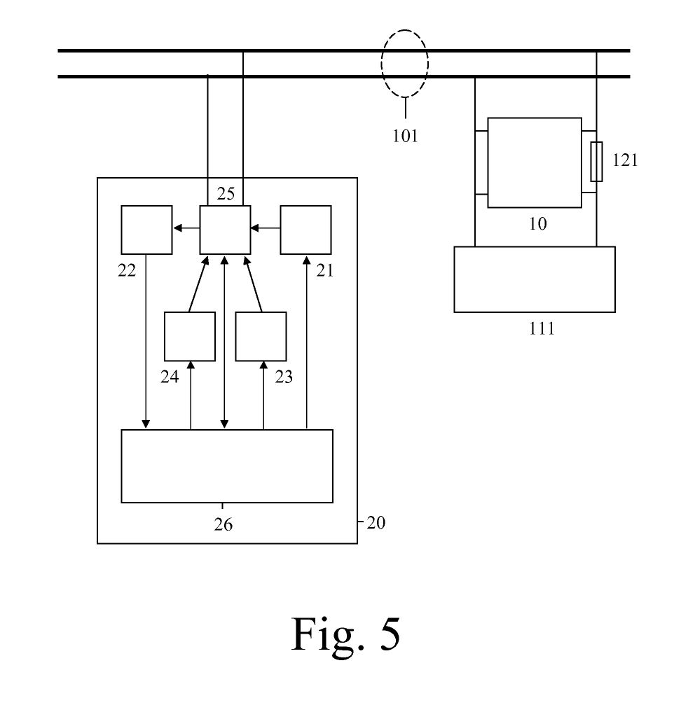

In the FIG. 2, an apparatus 10 is shown. The apparatus 10 reports a problem in a cable system comprising a cable 101 and a load 111 connected to the cable 101 via a fuse 121. The apparatus 10 comprises a first circuit 1 for detecting the fuse 121 going from a conducting mode to a non-conducting mode or having reached a non-conducting mode. The apparatus 10 further comprises a second circuit 2 connectable to the cable 101 for, in activated mode, receiving a first pulse signal from a device 20 connected to the cable 101, which device 20 is shown in the FIG. 5 and further discussed at the hand of the FIG. 5. In response to a reception of the first pulse signal, the second circuit 2 transmits a second pulse signal to the device 20. The apparatus 10 further comprises a third circuit 3 for activating the second circuit 2 in response to a detection result from the first circuit 1. So, at a start of the apparatus 10, the second circuit 2 is in a de-activated mode.

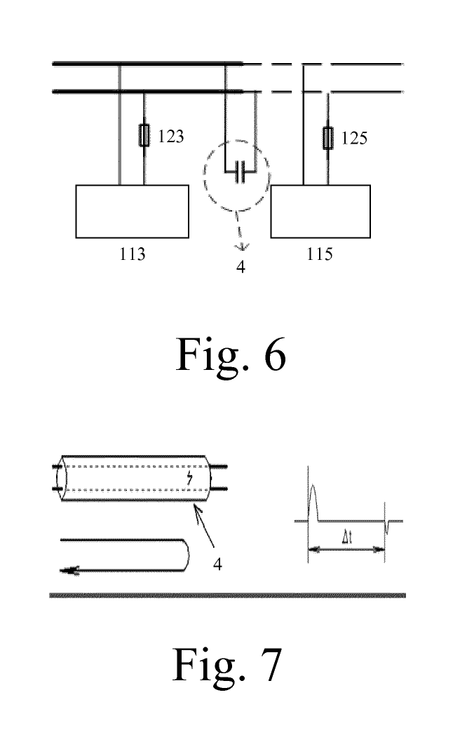

Preferably, the second pulse signal is a reflection of the first pulse signal, and a duration of the first pulse signal is smaller than 2 msec. as shown in the FIGS. 6 and 7 and further discussed at the hand of the FIGS. 6 and 7.

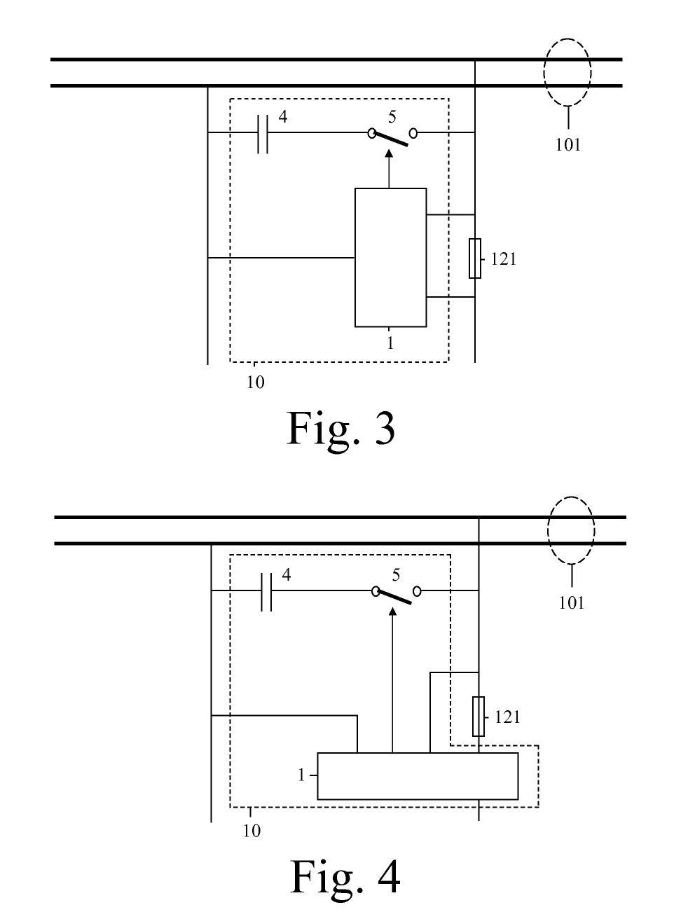

In the FIG. 3, a first embodiment of the apparatus 10 is shown. Here, as an example only, the second circuit 2 comprises a signaling capacitor 4, and the third circuit 3 comprises a switch 5. The signaling capacitor 4 and the switch 5 are connected serially and form part of a first serial connection coupled to both conductors of the cable 101. The fuse 121 and the load 111 (the load 111 is not shown here) form part of a second serial connection coupled in parallel to the first serial connection. Here, the first circuit 1 has a first terminal coupled to the first conductor and to one side of the fuse 121, a second terminal coupled to the other side of the fuse 121, and a third terminal coupled to the second conductor of the cable 101. This first circuit 1 for example comprises a detector for detecting a voltage signal present across the load 111 or across the fuse 121 or detecting another signal representative for the fuse 121 going from the conducting mode to the non-conducting mode or having reached the non-conducting mode. The first circuit 1 may further for example comprise a comparator for comparing the voltage signal with a first reference signal. In response to a change in the voltage signal, such as an increase of the voltage signal present across the fuse 121 or a decrease of the voltage signal present across the load 111, the first circuit 1 brings the switch 5 into a conducting mode. Preferably, the switch 5 stays in this conducting mode until a reset of the switch 5. As a result, in response to the fuse 121 getting broken, the signaling capacitor 4 is activated and able to receive the first pulse signal and transmit the second pulse signal etc. as further described at the hand of the FIGS. 6 and 7.

In the FIG. 4, a second embodiment of the apparatus 10 is shown. Here, again as an example only, the second embodiment differs from the first embodiment in that the first circuit 1 has a first terminal coupled to the first conductor and to one side of the fuse 121, a second terminal coupled to the other side of the fuse 121, a third terminal coupled to the second conductor of the cable 101 and to one side of the load 111, and a fourth terminal coupled to the other side of the load 111. This first circuit 1 for example comprises a detector for detecting a current signal flowing through the load 111 or through the fuse 121 or detecting another signal representative for the fuse 121 going from the conducting mode to the non-conducting mode or having reached the non-conducting mode. The first circuit 1 may further for example comprise a comparator for comparing the current signal with a second reference signal. In response to a change in the current signal, such as a decrease of the current signal flowing through the load 111 or through the fuse 121, the first circuit 1 brings the switch 5 into a conducting mode. Preferably, the switch 5 stays in this conducting mode until a reset of the switch 5. As a result, in response to the fuse 121 getting broken, the signaling capacitor 4 is activated and able to receive the first pulse signal and transmit the second pulse signal etc. as further described at the hand of the FIGS. 6 and 7.

In the FIG. 5, a device 20 is shown. The device 20 for searching for the problem in the cable system comprising the cable 101 and the load 111 connected to the cable 101 via the fuse 121 comprises for example an interface 25 coupled to the conductors of the cable 101. The device 20 further comprises for example a transmitter 21 coupled to the interface 25 for transmitting the first pulse signal to the apparatus 10 and a receiver 22 coupled to the interface 25 for receiving the second pulse signal from the apparatus 10. This second pulse signal is indicative for the problem, and a time-interval between a transmission of the first pulse signal and a reception of the second pulse signal is indicative for a location of the problem. The device 20 further comprises for example a processor 26 coupled to the transmitter 21, the receiver 22 and the interface 25 for controlling and/or calculation and/or presentation purposes, possibly via a man-machine-interface not shown and coupled to the processor 26.

Preferably, the second pulse signal may be a reflection of and have a smaller amplitude than the first pulse signal, and a duration of the first pulse signal may be smaller than 2 msec. Possibly, in case the apparatus 10 comprises the signaling capacitor 4 and in case the load 111 comprises a storing capacitor 202, the device 20 may be further provided with a charger 23 coupled to the interface 25 and the processor 26 for producing a charging signal for charging the signaling capacitor 4 and the storing capacitor 202, and with a discharger 24 coupled to the interface 25 and the processor 26 for discharging the signaling capacitor 4 without discharging the storing capacitor 202 as further described at the hand of the FIGS. 6, 7 and 8. An amplitude of the first pulse signal may then need to be smaller than an amplitude of a voltage signal present across the charged storing capacitor 202.

In the FIG. 6, a problem occurrence is shown. The fuses 123 and 125 are in conducting modes. The fuse 124 is no longer in a conducting mode, and as a result, the signaling capacitor 4 has been activated.

In the FIG. 7, a problem report is shown. A relatively large first pulse signal is transmitted by the device 20 to the loads 111-115. Between the loads 113 and 115, the signaling capacitor 4 has been activated, and this signaling capacitor 4 will block the relatively large first pulse signal and convert it into a reflected relatively small second pulse signal here at a reversed polarity that goes back to the device 20. A time-interval Δt between a transmission of the first pulse signal and a reception of the second pulse signal is indicative for a location of the problem, when the speed of the pulse signals when going through the cable 101 is known (for example about 200 m/μsec.).

Usually, the third circuit 3 in the apparatus 10 will be able to activate the second circuit 2 during the night (in case the corresponding fuse gets broken), when the loads 111-115, such as lamps, are consuming power, and a feeding signal is being supplied via the cable 101 to the loads 111-115. When the switch 5 has a memory function, it will stay in the conducting mode until a reset of the switch 5. Then, during the day, when the loads 111-115, such as lamps, are not consuming power, and a feeding signal is not present, the transmitter 21 in the device 20 can transmit the first pulse signal and the receiver in the device 20 can receive the second pulse signal.

It should not be excluded that the apparatus 10 may be provided with its own power supply etc.

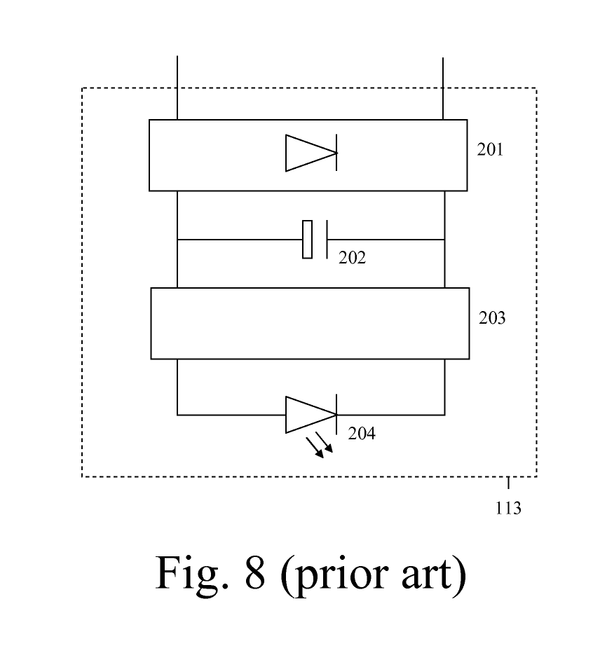

In the FIG. 8, a prior art load 113 is shown. This prior art load 113 comprises a rectifier bridge 201. Inputs of the rectifier bridge 201 are inputs of the load 113. Outputs of the rectifier bridge 201 are coupled to inputs of a dc-dc-converter 203 and to a storing capacitor 202. Outputs of the dc-dc-converter 203 are coupled to one or more light emitting diodes 204. Here, even in case the signaling capacitor 4 at one of the loads 111-115 has been activated, it will not reflect the first pulse signal, owing to the fact that the storing capacitor 202 at another one of the loads 111-115 which is located between the device 20 and said one of the loads 111-115 will block this first pulse signal and convert it into the reflected second pulse signal that goes back to the device 20 (the storing capacitor 202 will usually have a capacitance value that will be larger than a capacitance value of the signaling capacitor 4).

To overcome this problem, the charger 23 in the device 20 may produce a charging signal for charging the signaling capacitor 4 and the storing capacitors 202, and the discharger 24 in the device 20 may discharge the signaling capacitor 4 without discharging the storing capacitors 202. This can be easily arranged owing to the fact that the rectifier 201 will prevent the storing capacitors 202 from being discharged via the cable system. An amplitude of the first pulse signal may then need to be smaller than an amplitude of a voltage signal present across the charged storing capacitor 202. As a result, the first pulse signal can no longer be blocked and reflected by the storing capacitors 202, that have been charged via the charging signal, but the first pulse signal will be converted by the signaling capacitor 4 into the second pulse signal etc. owing to the fact that this signaling capacitor 4 has been discharged earlier etc.

Many alternatives will be possible to the embodiments shown in the FIG. 2-8. For example, in the FIGS. 3 and 4, the signaling capacitor 4 and the switch 5 may each be replaced by one or more other components and/or may each be connected otherwise. For example, in the FIGS. 3 and 4, the first circuit 1 may consist of different sub-circuits and/or may be connected differently. As a very simple example, the first circuit 1 may be a coil of a relay, with the switch 5 then comprising the contacts of this relay. When the fuse 121-125 stops being conductive, the relay goes into another mode and its contacts are mutually connected (here, of course, the relay should be capable of experiencing a difference between (A) the fuse 121-125 stopping to conduct and (B) the power on the cable 101 being cut off, so more circuitry may in this particular case be necessary). More complicated embodiments of the first circuit 1 are therefore not to be excluded and may comprise a transistor, a thyristor, a triac etc. possibly with further circuitry etc. Similarly, the second and third circuits 2, 3 may comprise a transistor, a thyristor, a triac etc. possibly with further circuitry etc.

For example in the FIG. 5, in the device 20, the interface 25 can be left out in case the transmitter 21, the receiver 22, the charger 23 and the discharger 24 can communicate more directly with the cable 101. Further, some or all functions of the transmitter 21, the receiver 22, the charger 23 and the discharger 24 may be integrated into the processor 26, and vice versa. Any unit 21-26 may be divided into sub-units, and any pair of units 21-26 may be combined into a larger unit etc. Finally, in the FIG. 8, the rectifier bridge 201, the storing capacitor 202, the dc-dc-converter 203 and the one or more light emitting diodes 204 of whatever kind and in whatever construction are examples only, other kinds of loads 111-115 are not to be excluded. Further circuitry may be added to improve the charging/discharging situation.

Summarizing, apparatuses 10 report problems in cable systems comprising cables 101 and loads 111 connected to the cables 101 via fuses 121 and comprise first circuits 1 for detecting the fuses 121 going from conducting modes to non-conducting modes or having reached non-conducting modes, second circuits 2 for receiving first pulse signal from devices 20 connected to the cables 101 and in response to receptions of the first pulse signals transmitting second pulse signals to the devices 20 and third circuits 3 for activating the second circuits 2 in response to detection results from the first circuits 1. The devices 20 search for the problems and comprise transmitters 21 for transmitting the first pulse signals to the apparatuses 10 and receivers 22 for receiving the second pulse signals from the apparatuses 10. The second pulse signals are indicative for the problems, and time-intervals between transmissions of the first pulse signals and receptions of the second pulse signals are indicative for locations of the problems.

While the invention has been illustrated and described in detail in the drawings and foregoing description, such illustration and description are to be considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting the scope.

1. An apparatus for reporting a problem in a cable system, the cable system comprising a cable and a load connected to the cable via a fuse, the apparatus comprising:
a first circuit for detecting the fuse going from a conducting mode to a non-conducting mode or having reached a non-conducting mode,
a second circuit for, when activated, receiving a first pulse signal from a device connected to the cable and in response to a reception of the first pulse signal transmitting a second pulse signal to the device, and
a third circuit for activating the second circuit in response to a detection result from the first circuit.

2. The apparatus as defined in claim 1, the second pulse signal being a reflection of the first pulse signal.

3. The apparatus as defined in claim 1, a duration of the first pulse signal being smaller than 2 msec.

4. The apparatus as defined in claim 1, the first circuit comprising a detector for detecting a current signal flowing through the load or through the fuse or detecting a voltage signal present across the load or across the fuse or detecting another signal representative for the fuse going from the conducting mode to the non-conducting mode or having reached the non-conducting mode.

5. The apparatus as defined in claim 1, the second circuit comprising a signaling capacitor, and the third circuit comprising a switch.

6. The apparatus as defined in claim 5, the signaling capacitor and the switch forming part of a first serial connection, the fuse and the load forming part of a second serial connection, the first and second serial connections being coupled in parallel to each other.

7. The apparatus as defined in claim 5, the switch going into a conducting mode in response to the detection result from the first circuit and staying in this conducting mode until a reset of the switch.

8. An arrangement comprising the apparatus as defined in claim 1 and further comprising the load and/or the fuse.

9. A device for searching for a problem in a cable system, the cable system comprising a cable and a load connected to the cable via a fuse, the device comprising:
a transmitter for transmitting a first pulse signal to an apparatus as defined in claim 1, and
a receiver for receiving a second pulse signal from the apparatus, the second pulse signal being indicative for the problem, and a time-interval between a transmission of the first pulse signal and a reception of the second pulse signal being indicative for a location of the problem.

10. The device as defined in claim 9, the second pulse signal being a reflection of and having a smaller amplitude than the first pulse signal.

11. The device as defined in claim 9, a duration of the first pulse signal being smaller than 2 msec.

12. The device as defined in claim 9, the apparatus comprising a signaling capacitor, and a load coupled to another apparatus comprising a storing capacitor, the device further comprising:
a charger for producing a charging signal for charging the signaling capacitor and the storing capacitor, and
a discharger for discharging the signaling capacitor without discharging the storing capacitor, an amplitude of the first pulse signal being smaller than an amplitude of a voltage signal present across the charged storing capacitor.

13. A cable system comprising a cable and a load connected to the cable via a fuse and further comprising the apparatus as defined in claim 1 and/or the device.

14. A package system comprising the apparatus as defined in claim 1 and the device.

15. A method for searching for a problem in a cable system, the cable system comprising a cable and a load connected to the cable via a fuse, the method comprising a first step of transmitting a first pulse signal from a device to an apparatus for reporting the problem in the cable system, the apparatus being arranged to detect the fuse going from a conducting mode to a non-conducting mode or having reached a non-conducting mode, to receive the first pulse signal, and to, in response to a reception of the first pulse signal and in response to a detection result, transmit a second pulse signal to the device, and the method comprising a second step of receiving the second pulse signal, the second pulse signal being indicative for the problem, and a time-interval between a transmission of the first pulse signal and a reception of the second pulse signal being indicative for a location of the problem.
